(19) United States
(12) Patent Application Publication
(10) Pub. No.: US 2025/0181273 A1
(43) Pub. Date: Jun. 5, 2025

(54) PARALLEL FOLDING AND HOST WRITE HANDLING

(71) Applicant: Micron Technology, Inc., Boise, ID (US)

(72) Inventors: Jameer Mulani, Bangalore (IN); Nitul Gohain, Bangalore (IN); Amiya Banerjee, Bangalore (IN); Anilkumar Rameshbhai Sindhi, Hyderabad (IN)

(21) Appl. No.: 18/954,258

(22) Filed: Nov. 20, 2024

Related U.S. Application Data
(60) Provisional application No. 63/604,779, filed on Nov. 30, 2023.

(51) Int. Cl. G06F 3/06

(52) U.S. Cl. CPC G06F 3/0659; G06F 3/0604; G06F 3/0673

(57) ABSTRACT

Methods, systems, and devices for parallel folding and host write handling are described. A memory system may perform a first program operation on a first die as part of a first folding operation, the first program operation having a duration. During the duration, the memory system may perform at least a portion of a second program operation on a second die as part of a second folding operation and perform a host write. For example, a host system may transmit a command to write data to the memory system during the duration of the first program operation. Based on the command, the memory system may suspend (e.g., delay) the second folding operation to write the data and resume (e.g., initiate) the second program operation after completing the write operation.

### CROSS REFERENCE

The present application for patent claims the benefit of U.S. Provisional Patent Application No. 63/604,779 by Mulani et al., entitled “PARALLEL FOLDING AND HOST WRITE HANDLING,” filed Nov. 30, 2023, assigned to the assignee hereof, and expressly incorporated by reference herein.

### TECHNICAL FIELD

The following relates to one or more systems for memory, including parallel folding and host write handling.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports parallel folding and host write handling in accordance with examples as disclosed herein.

FIG. 2 shows an example of a data transfer diagram that supports parallel folding and host write handling in accordance with examples as disclosed herein.

FIGS. 3 and 4 show examples of timing diagrams that support parallel folding and host write handling in accordance with examples as disclosed herein.

FIG. 5 shows a block diagram of a memory system that supports parallel folding and host write handling in accordance with examples as disclosed herein.

FIG. 6 shows a flowchart illustrating a method or methods that support parallel folding and host write handling in accordance with examples as disclosed herein.

### DETAILED DESCRIPTION

A memory system may support storing information in memory devices including memory cells capable of storing various quantities of bits of information (e.g., 1, 2, 3, or 4 bits of information). The memory system may include higher storage density memory cells (e.g., which may be referred to as multi-programming pass cells), such as quad-level cells (QLCs), and may include lower storage density memory cells (e.g., which may be referred to as single programming pass cells), such as single-level cells (SLCs), multi-level cells (MLCs), and triple-level cells (TLCs). Writing data to multi-programming pass cells may be associated with relatively high programming times, for example, due to involving multiple program operations (e.g., stages, passes) to write the data. As a result, writing data to single programming pass cells (e.g., SLCs, MLCs, TLCs) may be faster than writing data to multi-programming pass cells (e.g., QLCs). As such, the memory system may initially write data (e.g., host data) to single programming pass cells, for example, to support faster host write performance (e.g., relative to initially storing the host data to QLCs) and then fold (e.g., transfer) the data to multi-programming pass cells, for example, to increase storage density and efficiency.

Some host systems may have host write performance constraints (e.g., at least 60 megabytes (MB) per second (MB/s)) associated with the memory system. To support satisfying the host write performance constraints, the memory system may be configured to make at least one die available (e.g., unoccupied with performing one or more operations such as folding) for host writes, as dies occupied with some operations, such as folding, may be unavailable for host writes. In some cases, the memory system may throttle (e.g., reduce) a performance of host writes to be less than or equal to a performance of the folding. Otherwise, over time, a rate of folding data from lower storage density blocks (e.g., blocks of lower storage density cells, single programming pass cells) may be less than a rate of writing host data to the lower storage density blocks, such that the lower storage density blocks may be filled by data associated with the host writes before the memory system is able to fold the data to the higher storage density blocks (e.g., multi-programming pass cells) and erase the lower storage density blocks. If the lower storage density blocks are filled, the host write performance may then be limited by the folding performance. That is, the rate of host writes may be limited by the rate of folding (e.g., QLC folding). But, in some cases, the folding performance may be less than the host write performance constraints, and thus the memory system may be unable to operate according to the host write performance constraints. Accordingly, increasing folding performance may be needed to satisfy host write performance constraints.

In accordance with examples as disclosed herein, the memory system may be configured to support a higher rate of folding and, consequently, a higher rate of host writing such that host write performance constraints may be satisfied (e.g., met, exceeded). For example, the memory system may perform a respective first program operation (e.g., a programming pass part of a folding operation) as part of a first folding operation on a first die during a duration of time in which the memory system may accommodate (e.g., perform) one or more host writes on a second die and perform at least a portion of a respective second program operation as part of a second folding operation on the second die. For instance, the one or more host writes may take less time to complete than the duration of the first program operation, and time that the second die would have remained idle (e.g., due to being reserved to accommodate host writes) may instead be spent performing at least part of the second program operation. In other words, instead of reserving one or more dies to accommodate host writes, the memory system may perform a respective program operation as part of respective folding operations on multiple (e.g., 2, all) dies and temporarily interrupt (e.g., suspend, delay) a program operation on a given die to perform a host write on the die.

For example, the host system may transmit a write command to the memory system, and the memory system may suspend (e.g., delay) the program operation on one of the dies (e.g., the second die) to write the data to the die, and then resume (e.g., initiate) the program operation on that die after the write is performed. The memory system may alternate between dies for which folding is suspended to perform the host write, such that after the duration, a different die (e.g., the first die) may be used to perform one or more host writes received during a second duration. The increased time spent performing program operations as part of folding operations increases folding operation performance and efficiency. As a result, host writing performance may be increased such that the memory system may satisfy host write performance constraints, among other benefits.

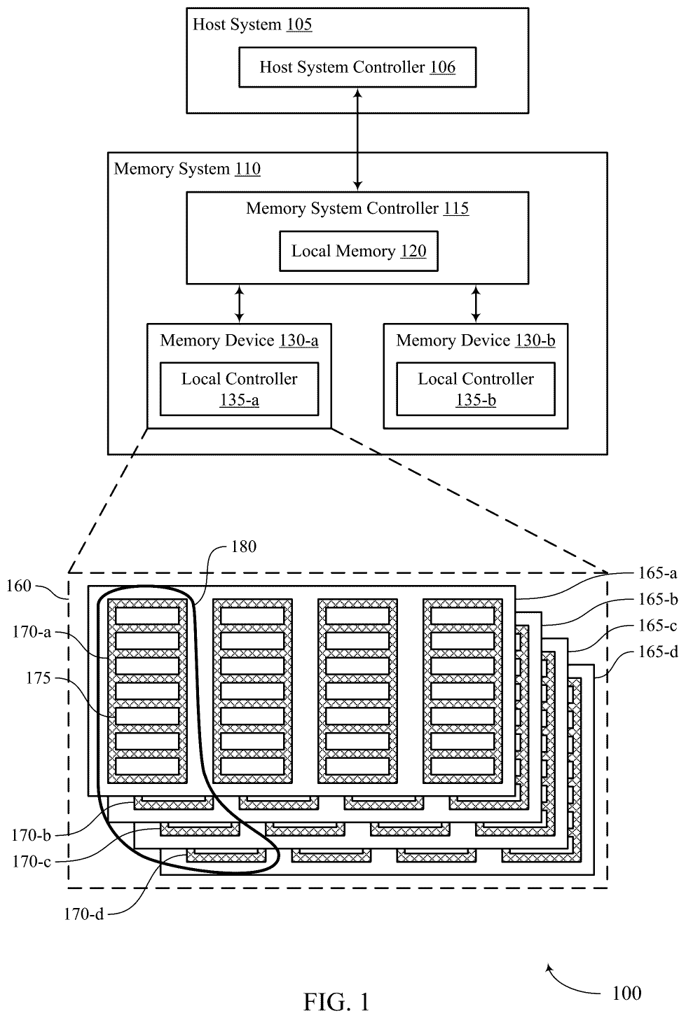

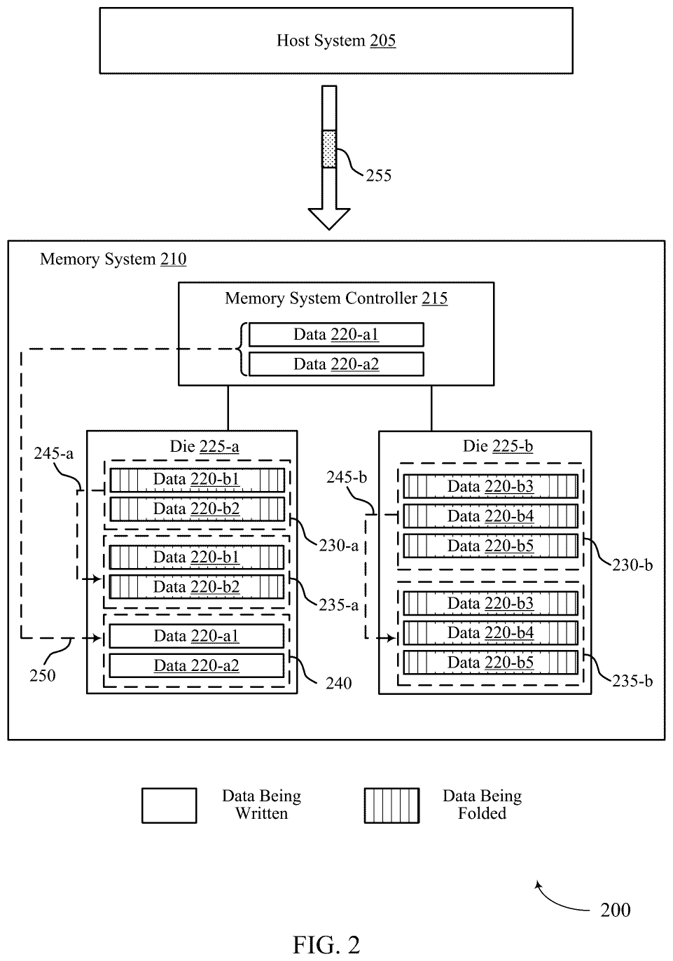

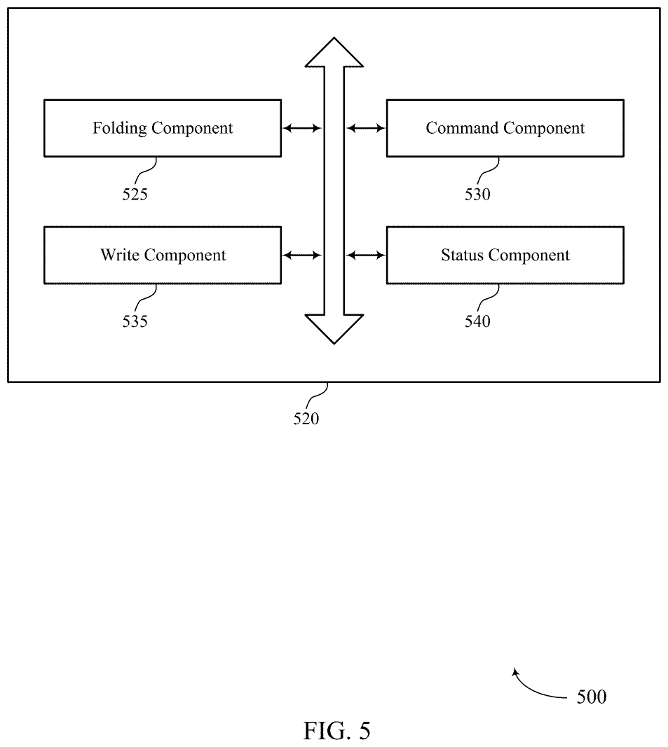

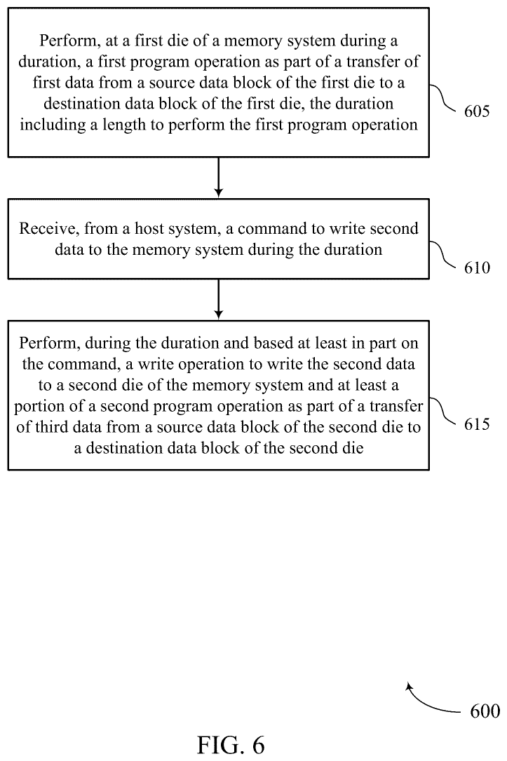

Features of the disclosure are initially described in the context of a systems with reference to FIG. 1. Features of the disclosure are described in the context of a data transfer diagram and timing diagrams with reference to FIGS. 2 through 4. These and other features of the disclosure are further illustrated by and described in the context of an apparatus diagram and flowchart that relate to parallel folding and host write handling with reference to FIGS. 5 through 6.

FIG. 1 shows an example of a system 100 that supports parallel folding and host write handling in accordance with examples as disclosed herein. The system 100 includes a host system 105 coupled with a memory system 110. The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as SLCs. Additionally, or alternatively, a NAND memory device 130 may include memory cells configured to each store multiple bits of information, which may be referred to as MLCs if configured to each store two bits of information, as TLCs if configured to each store three bits of information, as QLCs if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

The system 100 may include any quantity of non-transitory computer readable media that support parallel folding and host write handling. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

The memory system 110 may include multi-programming pass cells (e.g., QLCs) and single programming pass cells (e.g., SLCs, MLCs, TLCs). That is, the memory system 110 (e.g., the memory system controller 115) may perform multiple program operations (e.g., passes, stages of a write operation) to write data to multi-programming pass cells, whereas to write data to single programming pass cells, the memory system 110 may perform a single program operation. As such, writing to single programming pass cells may be faster than writing to multi-programming pass cells. Accordingly, in some examples, the memory system 110 may initially write data (e.g., host data) to single programming pass cells, for example, to support faster host write performance (e.g., relative to initially writing the host data to QLCs) and then fold (e.g., transfer) the data to multi-programming pass cells, for example, to increase the storage density and efficiency.

Some host systems 105 may have host write performance constraints (e.g., a minimum writing speed, such as 60 MB/s) for the memory system 110. To support satisfying the host write performance constraints, the memory system 110 may leave at least one die 160 available (e.g., unoccupied with performing folding) for host writes, as other dies 160 may be occupied with folding and unavailable for host writes. In some cases, the memory system 110 may throttle (e.g., reduce) a performance of host writes to be less than or equal to a performance of the folding, because if data blocks (e.g., virtual blocks 180, blocks 170) including single pass programming cells are filled, the host write performance may be limited by the folding performance anyway. In some cases, the folding performance may be less than the host write performance constraints, and thus the memory system 110 may be unable to operate according to the host write performance constraints. Accordingly, increasing folding performance may be necessary to satisfy host write performance constraints.

In accordance with examples as disclosed herein, the memory system 110 may be configured to support a higher rate of folding and, consequently, a higher rate of host writing such that host write performance constraints may be satisfied (e.g., met, exceeded). For example, the memory system 110 may perform a respective first program operation as part of a first folding operation on a first die 160 during a duration of time in which the memory system 110 may accommodate (e.g., perform) one or more host writes on a second die 160 and perform at least a portion of a respective second program operation as part of a second folding operation on the second die 160 (e.g., the one or more host writes may take less time to complete than the first program operation, and time that the second die would have remained idle may instead be spent performing at least part of the second program operation).

For instances, the memory system 110 may perform a respective program operation (e.g., a pass of a folding operation) in multiple (e.g., 2, all) dies 160. One or more dies 160 (e.g., the second die 160), in addition to being used to perform the respective program operations, may be used to perform host writes (e.g., perform host writes if the host system 105 transmits write commands). Other dies 160 may be dedicated to performing program operations as part of respective folding operations (e.g., QLC folding). For example, the host system 105 may transmit a write command to the memory system 110 and the memory system may suspend (e.g., delay) the program operation (e.g., a QLC programming pass) on one of the dies 160 (e.g., the second die 160) to write the data to the die 160 and then resume (e.g., initiate) the program operation on that die 160 after the write is performed. The memory system 110 may alternate between dies 160 for which folding is suspended to perform the host write, such that after the duration (e.g., the first program operation), a different die 160 (e.g., the first die 160) may be used to perform one or more host writes received during a second duration. The memory system 110 may alternate, or rotate, between dies in any order and the memory system 110 may perform host writes to same die 160 during multiple (e.g., non-consecutive) durations.

In addition to applicability in memory systems as described herein, techniques for a method for handling host writes in parallel to QLC folding may be generally implemented to improve the performance (including for gaming applications) of various electronic devices and systems. Some electronic device applications, including gaming and other high-performance applications, may be associated with relatively high processing requirements while also benefitting from relatively quick response times to improve user experience. As such, increasing processing speed, decreasing response times, or otherwise improving the performance electronic devices may be desirable. Implementing the techniques described herein may improve the performance of electronic devices by reducing host write throttling and improving host write and folding performances (e.g., rates), which may decrease processing and/or latency times, improve response times, and/or otherwise improve user experience, among other benefits.

FIG. 2 shows an example of a data transfer diagram 200 that supports parallel folding and host write handling in accordance with examples as disclosed herein. The data transfer diagram 200 may illustrate operations of one or more components of a system 100, as described with reference to FIG. 1. For example, the data transfer diagram 200 illustrates a host system 205 and memory system 210 including a memory system controller 215, where the host system 205, the memory system 210, and the memory system controller 215 may be examples of a host system 105, memory system 110 and a memory system controller 115, respectively, as described with reference to FIG. 1. The data transfer diagram 200 may illustrate writing data 220 to and transferring (e.g., folding) data 220 between blocks of one or more dies 225, which may be examples of one or more dies 160 as described with reference to FIG. 1. The memory system 210 may support writing data 220 to a die 225.

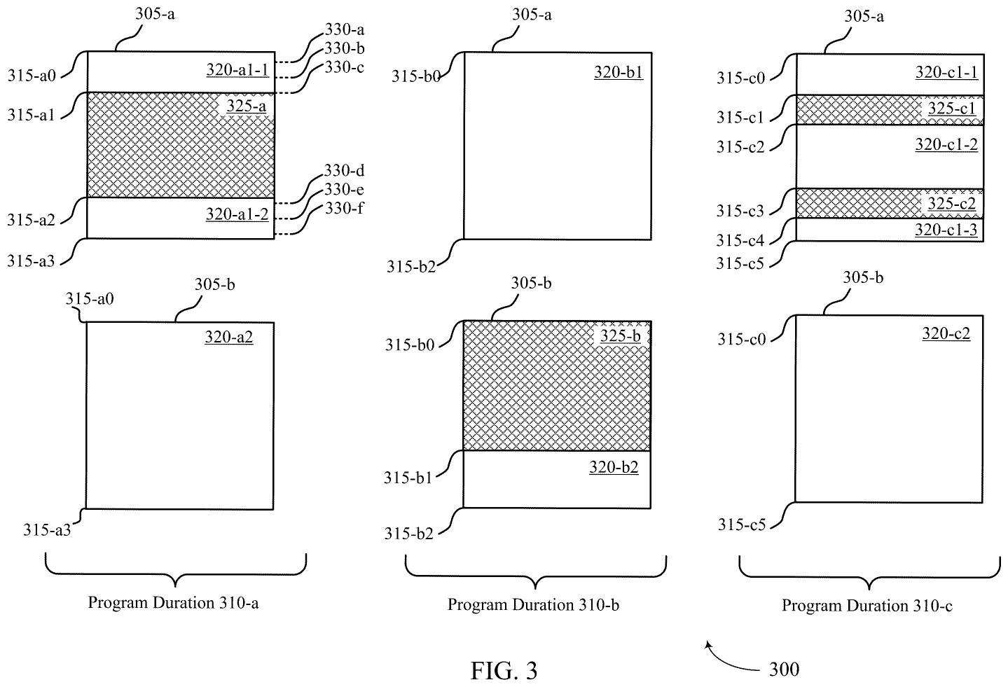

The dies 225 may support performing folding operations 245 in which data is folded (e.g., transferred) from blocks 230 to blocks 235 within the die 225 (e.g., or another die 225). The timing of folding operations 245 and write operations 250 is discussed in more detail with reference to FIG. 3. In some examples, the memory system controller 215 may represent a controller including volatile memory, such as SRAM, among other types of volatile memory. For example, the memory system controller 215 may include a buffer (e.g., including the local memory 120) that includes SRAM memory.

The memory system 210 may include any quantity of dies 225, and each die 225 may each include any quantity of blocks 230, blocks 235, and blocks 240, which may be referred to as data blocks. In some examples, the data blocks may be examples of virtual blocks 180 or blocks 170 as described with reference to FIG. 1. In the example of FIG. 2, the die 225-a may include a block 230-a, a block 235-a, and a block 240. The die 225-b may include a block 230-b and a block 235-b. Each of the blocks 230, 235 and 240 may be operable to store respective data 220 in one or more pages (e.g., pages 175) of the respective blocks 230, 235, and 240. In some examples, a block 230, 235, or 240 may represent a source data block or a destination data block depending on how the block is used during one or more access, write, or transfer operations. For example, a source data block 230 may be a data block from which data is transferred as part of a folding operation 245, a destination data block 235 may be a data block to which data is transferred as part of a folding operation 245, and a block 240 may be a data block to which the memory system 210 writes data as part of a write operation 250 associated with a write command 255 from the host system 205.

In some cases, the blocks 230, 235, and 240 may include SLCs, MLCs, TLCs, or QLCs (e.g., at a given time). That is, in some cases, memory cells of a data block may be programmed as one type of memory cell at a first time and as a second type of memory cell at a second time (e.g., after erasure of the data block). In some other cases, some data blocks may include a fixed (e.g., unchanging) type of memory cell. Lower storage density memory cells, (e.g., memory cells storing fewer bits per memory cell, such as SLCs, MLCs, and TLCs) may have faster program times (e.g., TPROG) compared to higher storage density memory cells, (e.g., QLCs). For example, SLCs and TLCs may have a TPROG of approximately 85 μs and 300 μs, respectively, whereas QLCs may have a TPROG of approximately 3 ms or longer. In some cases, programming data to (e.g., writing to) QLCs may include two-pass programming including performing two program operations (e.g., stages, passes) to accurately program one or more QLCs. For example, a first pass of programming a QLC may span a duration of 2 ms (among other possible durations), whereas a second pass of programming a QLC may span a duration of 3 ms (among other possible durations).

In some cases, data blocks (e.g., block 240) to which data is written as part of a host write may be data blocks that include single programming pass cells (e.g., lower storage density memory cells). For example, if used to store data as part of a host write, the block 240 may include lower storage density memory cells (e.g., SLCs, MLCs, or TLCs), which may support faster writing to the block 240. In some examples, blocks 230 may include lower storage density memory cells or higher storage density memory cells and be source data blocks for folding operations. The blocks 235 may include high storage density memory cells (e.g., QLCs) to enable compact information storage. In some examples, blocks 230 may include higher storage density memory cells, for example, if previously functioning as a destination data block for folding operations.

The memory system 210 may perform one or more write operations 250 in response to one or more write commands 255 received from a host system 205. For example, the memory system controller 215 may receive a write command 255 from the host system 205 to write data 220-a1 and 220-a2 to the memory system 210. The memory system controller 215 may temporarily store the data 220-a1 and 220-a2 within a buffer of the memory system controller 215 (e.g., a local memory 120). The memory system controller 215 may determine a location within the memory system 210 to which write the data 220-a1 and 220-a2, such as to one or more pages of the block 240. After storing the data within the buffer, the memory system controller 215 may write the data 220-a1 and 220-a2 to one or more pages of the block 240.

The memory system 210 may determine to transfer (e.g., fold) data 220 from one or more of the blocks 230 to one or more of the blocks 235. The memory system controller 215 may begin folding data 220 (e.g., initiate a transfer of the data 220, such as part of garbage collection) from pages of one or more blocks 230 to one or more blocks 235 (e.g., to free blocks 230 such that the blocks 230 may be erased) as part of a folding operation 245. In the example of FIG. 2, the memory system controller 215 may fold the data 220-b1 and 220-b2 from the block 230-a to the block 235-a (e.g., within the same die 225-a). Similarly, the memory system controller 215 may fold the data 220-b3 through 220-b5 from the block 230-b to the block 235-b. In some examples, data may be folded from a source data block 230 in one die 225 to a destination data block 235 in a different die 225.

In some examples, the memory system 210 may not support concurrent (e.g., parallel) folding and access operations (e.g., host writes) on a same die 225 at the same time. In some cases, the memory system 210 may reserve one or more dies 225 for host writes, while other dies 225 are involved in folding operations 245. In some cases, the memory system 210 may throttle (e.g., reduce) a performance of host writes to be less than or equal to a performance of the folding. Otherwise, over time, blocks 240 may be filled with data 220 faster than data from blocks 230 may be folded and erased to accommodate additional host writes. Additionally, in some cases, the buffer (e.g., cache) of the memory system controller 215 (e.g., a portion of the buffer allocated to support host writing) may begin to fill with data 220 due to the time duration for folding (e.g., to QLCs) being longer than the time duration for writing to blocks 240 (e.g., to SLCs, MLCs, or TLCs), such as if blocks 240 are unavailable (e.g., filled) to store the data 220. Thus, as the memory system controller 215 receives commands 255 indicating to write data 220 to one or more dies 225, the buffer may hold the data 220 instead of performing host write operations 250. If the buffer is filled, one or more write commands 255 may be rejected or delayed (e.g., host write operations 250 may be stalled). As a result, host write performance may be degraded due to slow folding operations, and in some cases, host write performance constraints may not be met.

As described herein, the memory system 210 may perform program operations (e.g., as part of folding operations 245) on multiple (e.g., all) dies 225 and suspend (e.g., or delay) the program operations on one or more of the dies 225 to perform one or more write operations 250. The memory system 210 does not reserve one or more dies 225 for host writing, but rather multiple (e.g., all) dies 225 may be used to perform folding operations 245 (e.g., program operations part of folding operations 245) and folding operations 245 on one die 225 (e.g., die 225-a) may be suspended or delayed to perform the write operation 250. For example, the memory system controller 215 may receive (e.g., from a host system 105) a command indicating to write data 220-a1 to a die 225 and may store the data 220-a1 in the buffer of the memory system controller 215. In response to receiving the write command 255, the memory system controller 215 may suspend or delay the folding operation 245-a on die 225-a and write the data 220-a1 to the die 225-a while the folding operation 245-a is suspended. After the write operation 250 is completed, the memory system controller 215 may resume the folding operation 245-a on the die 225-a. The folding operation 245-a and the write operation 250 may occur concurrently with the folding operations of one or more other dies 225 (e.g., folding operation 245-b on die 225-b).

The memory system 210 may alternate which dies are available to perform host write operations 250. As depicted in the data transfer diagram 200, die 225-a may perform the write operation 250. After a certain duration of time (e.g., the duration being a length of time to complete a program operation on the die 225-b as part of the folding operation 245-b, such as a programming pass during QLC folding), the memory system 210 may perform a write operation 250 on die 225-b. The memory system similarly may suspend or delay a folding operation on die 225-b to perform the write operation 250. After a second duration of time (e.g., the duration being a length of time to complete a second program operation on the die 225-a as part of the folding operation 245-a, such as a second programming pass during QLC folding), the memory system 210 may perform write operations 250 on a different die (e.g., die 225-a again, or another die 225 not depicted). The memory system 210 may switch between performing write operations 250 on the different dies 225 while respective folding operations 245 (e.g., QLC programming passes) are ongoing on the dies 225. Details associated with suspending or delaying program operations to accommodate host writes is further described with reference to FIG. 3.

The techniques described herein may provide increased efficiency and performance as well as reduced latency in operations of the memory system 210. For example, the time that the die 225-a would have remained idle (e.g., if the die 225-a were reserved for host writing for a duration in which a program operation is performed on the die 225-b) may instead be used for program operations (e.g., QLC programming, part of folding operations 245), which may increase a folding performance (e.g., a garbage collection performance), such as to 85 MB/s. Thus, the operations described herein may improve a latency of access operations (e.g., by reducing a throttling of host writes), which may enable the memory system 210 to meet one or more latency, host write, or customer constraints (e.g., a host write performance may be increased to satisfy a 60 MB/s constraint). Additionally, suspending or delaying program operations that are a part of folding operations 245 to perform write operations 250 may enable the use of a smaller size for the buffer for the memory system controller 215 while satisfying host write performance constraints, which may reduce a cost of the memory system 210.

FIG. 3 shows an example of a timing diagram 300 that supports parallel folding and host write handling in accordance with examples as disclosed herein. The timing diagram 300 may illustrate operations performed on a first die 305-a and a second die 305-b during three program durations 310 (e.g., that are subsequent in time). The dies 305 may be included in a memory system and may be examples of dies 160 or 225 described with reference to FIGS. 1 and 2, respectively. Each program duration 310 may correspond to a length of time for a program operation 320 that is a part of a folding operation to be completed (e.g., 2 ms, 3 ms, 4 ms, among other durations).

During the program durations 310, the memory system (e.g., memory system 210, memory system 110) may initiate, suspend, delay, resume, or complete program operations 320 (e.g., part of folding operations 245) and write operations on the dies 305 at respective times 315 within a respective program duration 310. A die 305 may be used to perform multiple write operations 325 during a program duration 310. The memory system may begin the performance of a write operation 325 at the start of the program duration 310 or during the program duration 310. In some examples, a write operation 325 may be performed in response to a write buffer of the memory system (e.g., a volatile memory device of a memory system controller, such as a portion of a local memory 120 allocated for supporting host writes) being full. In some examples, a write operation 325 may be performed while the write buffer has available space.

The timing diagram 300 includes three program durations 310 and two dies 305, however any quantity of program durations 310 and dies 305 are possible. The program durations 310-a, 310-b, and 310-c may be the same or different lengths of time. In some examples, a respective length of the program durations 310 may be based on whether the program durations 310 correspond a first or second pass of a QLC write operation, the first and second passes possibly having different durations (e.g., program duration 310-a corresponds to a first pass on the die 305-b, program duration 310-c corresponds to a second pass on the die 305-b). For example, a program duration 310 corresponding to a first programming pass of a multi-programming pass write operation (e.g., a QLC write operation) may be shorter than a program duration 310 corresponding to a second programming pass of the multi-programming pass write operation.

During the program duration 310-a, the memory system may perform a program operation 320-a1 (e.g., may perform a first portion 320-a1-1 of the program operation 320-a1) on the first die 305-a. For example, performance of the program operation 320-a1 may be a part of a transfer of first data from a source data block (e.g., block 230) of the die 305-a to a destination data block (e.g., block 235) of the die 305-a. The memory system may initiate and perform at least a portion of the program operation 320-a1 (e.g., the portion 320-a1-1) from a time 315-a0 until time 315-a1.

The program durations 310 may include various time intervals 330 (e.g., step points, check points) at which the memory system determines whether a write command to write host data has been received. For example, at time intervals 330 (e.g., time intervals 330-a through 330-f, the memory system may check for write commands from the host system. In the example of FIG. 3, the memory system may receive a write command and at time interval 330-c (e.g., at time 315-a1), the memory system may suspend (e.g., pause, interrupt) the program operation 320-a1 on the die 305-a and perform a write operation 325-a to write second data to the die 305-a in response to the write command while the program operation 320-a1 is suspended.

In some examples, the write operation 325-a may include overwriting one or more latches that contain the first data associated with the program operation 320-a1. For example, as part of transferring the first data from the source data block of the die 305-a to the destination data block, the memory system may write (e.g., transfer) the first data from the source data block to the one or more latches of the memory system (e.g., to subsequently write the latched first data to the destination data block). In some cases, to support performing the write operation 325-a, the memory system may overwrite the first data in the one or more latches with the second data (e.g., to support writing the second data to the die 305-a from the one or more latches). In some examples, the memory system may overwrite the one or more latches with the second data due to receiving the write command after the first data is written to the one or more latches. The memory system may rewrite the first data associated with the program operation 320-a1 to the one or more latches based on the overwriting and after the write operation 325-a is performed. The write operation 325-a may be completed (e.g., performed) in less time than the length of the program duration 310-a. That is, a duration to perform the write operation 325-a may be less than the program duration 310-a.

After (e.g., once) the write operation 325-a is complete at time 315-a2, the die 305-a may resume the program operation 320-a1 (e.g., may resume performing a second portion 320-a1-2 of the program operation 320-a1). The memory system may track the status of the program operation 320-a1 such that the program operation 320-a1 may be resumed at the point of the program operation 320-a1 at which the program operation 320-a1 was suspended to perform the write operation 325-a. In other words, the portion 310-a1-2 of the program operation 310-a1 may pick up where the portion 310-a1-1 left off. The memory system may also track the status of the write operation 325-a, for example, to determine at what time (e.g., time 315-a2) to resume the program operation 320-a1.

In some examples, the memory system may write the first data associated with the program operation 320-a1 from the one or more latches to a destination data block. The memory system may continue performing the program operation 320-a1 until the end of the program duration 310-a at time 315-a3. The memory system may continue checking for write commands at time intervals 330-d through 330-f between times 315-a2 and 315-a3. During the program duration 310-a, the second die 305-b may be used for performing a program operation 320-a2 (e.g., a first pass or a second pass of a QLC program operation). That is, during the program duration 310-a, the memory system may perform the program operation 320-a2 as part of a transfer of third data from a source data block of the die 305-b to a destination data block of the die 305-b.

The memory system may alternate between dies designated (e.g., used) for performing write operations 325. In some examples, the memory system may alternate between dies 305 for each write command. In some examples, the memory system may alternate between dies 305 for different program durations 310. For example, during the program duration 310-b, the second die 305-b may be used by the memory system to perform write operations 325 corresponding to write commands received during the length of the program duration 310-b. During the program duration 310-b, the first die 305-a may be dedicated to performing a program operation 320-b1 (e.g., a continuation of the program operation 320-a1, a first or second pass of a QLC program operation). In some examples, a write command may be received before a program duration 310 starts (e.g., before time 315-b0). The memory system may check for write commands during intervals of the program duration 310-b similar to the intervals 330 of program duration 310-a. In the example of FIG. 3, a write command may be received before the program duration 310-b, and the memory system may perform a write operation 325-b at time 315-b0 (e.g., the start time of the program duration 310-b) in response to the write command. In this case, the memory system may delay (e.g., instead of suspend) a program operation that the die 305-b would have initiated at time 315-b0 had it not started performing the write operation 325-b. Accordingly, after (e.g., once) the write operation 325-b is complete, at time 315-b1, the die 305-b may initiate and perform at least a portion of the program operation 320-b2 (e.g., until a time 315-b2 corresponding to an end time of the program duration 310-b).

Multiple write operations 325 may be performed during a single program duration 310. Here, a program operation 320 (e.g., program operation 320-c1) may be suspended multiple times during a program duration 310. For example, during a program duration 310-c, the memory system may use the first die 305-a for performing write operations 325 corresponding to write commands received during the length of the program duration 310-c. During the program duration 310-c, the second die 305-b may be used to perform a program operation 320-c2. The memory system may check for write commands during time intervals 330 (not shown) of program duration 310-c similar to the intervals 330 of program duration 310-a.

In the example of FIG. 3, the memory system may initiate a program operation 320-c1 (e.g., a first portion 320-c1-1 of the program operation 320-c1) at time 315-c0 (e.g., the start time of the program duration 310-c). The memory system may receive a write command after the start time 315-c0 of the program duration 310-c (e.g., between the time 315-c0 and a time 315-c1). The memory system may suspend the program operation 320-c1 and perform the write operation 325-c1 while the program operation 320-c1 is suspended. At time 315-c2, the write operation 325-c1 may be completed and the memory system may resume the program operation 320-c1 (e.g., may start performing a second portion 320-c1-2 of the program operation 320-c1). The memory system may receive an additional write command after the time 315-c2 (e.g., between the time 315-c2 and 315-c3) and may suspend the program operation 320-c1 again, at time 315-c3, to perform another write operation 325-c2. At time 315-c4, the write operation 325-c1 may be completed and the memory system may resume the program operation 320-c1 (e.g., may start performing a third portion 320-c1-3 of the program operation 320-c1) and perform the program operation 320-c1 until time 315-c5 (e.g., an end of the program duration 310-c).

In some examples, each program duration 310 may be referred to as an iteration. An iteration may have a duration corresponding to a duration of a programming pass, such as 2100 microseconds (μs), or another length of time. In a first iteration (e.g., program duration 310-a), a buffer (e.g., a 576 KB SRAM buffer) associated with the memory system may have available space (e.g., the buffer may be free). The memory system may receive a host write command and perform a corresponding write operation 325 in die 305-a. In some examples, the die 305-a may have multiple planes (e.g., planes 165) and the memory system may write to one or more of the planes of the die 305-a. In some examples, the memory system may write to TLCs and the write operation 325 may cause the memory system to be busy for 900 μs, or another length of time. For a remainder of the program duration 310 (e.g., 1200 μs), the die 305-a may be used to perform at least a portion of a first QLC program operation or other operations (e.g., that are a part of folding operations to transfer data from source data blocks to destination data blocks). In the first iteration, other dies of the memory system (e.g., die 305-b), may be used to perform at least a portion of a second QLC program operation for the entire duration.

In a second iteration (e.g., program duration 310-b) lasting a second duration, the buffer associated with the memory system may have available space (e.g., the buffer may be free). The memory system may receive a second host write command and perform a corresponding second write operation 325 in die 305-b. In some examples, the memory system may write to TLCs and the second write operation 325 may cause the memory system to be busy for 900 μs, or another length of time. For a remainder of the second duration (e.g., 1200 μs), the die 305-b may be used to perform at least a portion of a third QLC program operation or other operations. In the second iteration, other dies of the memory system (e.g., die 305-a), may be used to perform at least a portion of a fourth QLC program operation for the entire duration.

The memory system may continue to perform QLC program and writing operations, alternating between the dies to perform the write operations 325. For example, a third iteration may be similar to the first operation and a fourth iteration may be similar to a second operation.

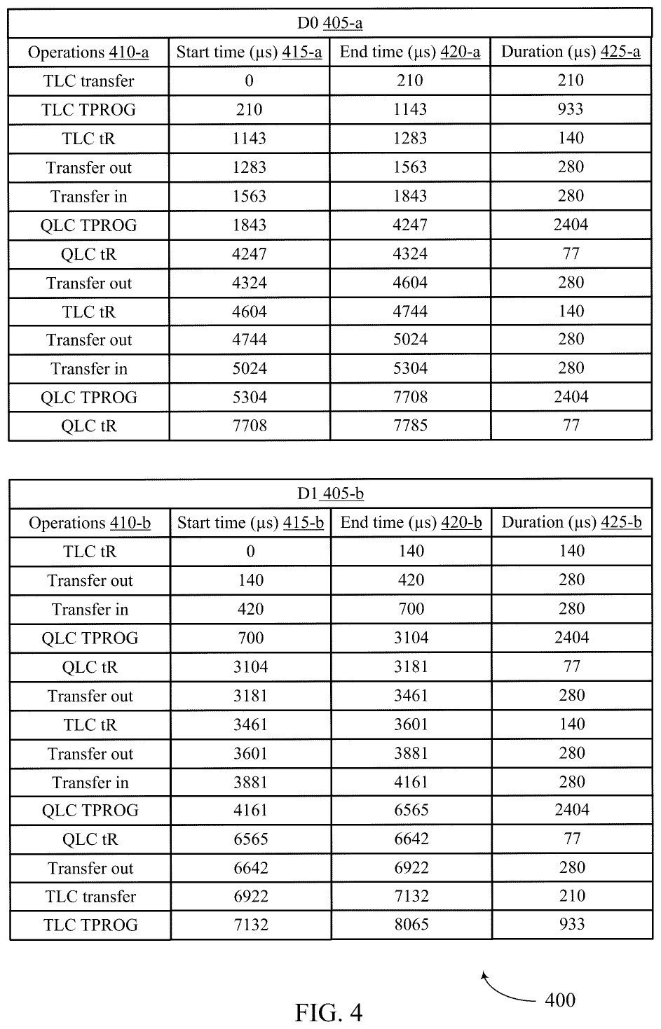

FIG. 4 shows an example of a timing diagram 400 that supports parallel folding and host write handling in accordance with examples as disclosed herein. The timing diagram 400 may be an example of timings the timing diagram 300 and may illustrate various operations 410, and corresponding start times 415, end times 420, and durations 425, performed on dies 405 in a memory system such as a memory system 110 or 210. The dies 405 may be examples of dies 305, dies 225, or dies 160, or a combination thereof. Two dies, DO (die 405-a) and DI (die 405-b) are depicted, however any quantity of dies is possible. The operations 410, start times 415 (e.g., start times 415-a and 415-b for dies 405-a and 405-b, respectively), end times 420 (e.g., end times 420-a and 420-b for dies 405-a and 405-b, respectively), and durations 425 (e.g., durations 425-a and 425-b for dies 405-a and 405-b, respectively) are included as non-limiting examples; a memory system may perform various operations that correspond to various start times, end times, and durations different than those illustrated in FIG. 4. In some examples, the operations 410 of the dies 405 may be sub-operations of folding operations (e.g., folding operations 245) and write operations (e.g., write operation 250, write operation 325). In some examples, the operations 410 may have start times 415 and end times 420 that do not correspond with the program durations 310.

The memory system may perform various operations 410-a on die 405-a. For example, at start time 0 μs, the memory system may perform a TLC transfer for 210 μs. At time 210 μs, the memory system may perform a TLC program operation that lasts 933 μs. The TLC program operation may correspond to at least a portion of a write operation 325. In some examples, a QLC program operation that is a part of a folding operation may be suspended or delayed to perform the TLC program operation. At time 1143 μs, the memory system may perform a TLC read for a duration of 140 μs, such as to verify the success of the TLC program operation. At time 1283 μs, the memory system may transfer data out of a buffer of the memory system (e.g., cache, volatile memory of a memory system controller) for a duration of 280 μs. At time 1563 μs, the memory system may transfer data into the buffer for a duration of 280 μs.

At time 1843 μs, the memory system may perform at least a portion of a QLC program operation (e.g., a first or second programming pass, a portion of a first or second programming pass) for a duration of 2404 μs. At time 4247 μs, the memory system may perform a QLC read for a duration of 77 μs, such as to verify the success of the QLC program operation. The QLC program operation may correspond to at least a portion of a program operation 320. At time 4324 μs, the memory system may transfer data out of the buffer for a duration of 280 μs. At time 4604 μs, the memory system may perform a TLC read for a duration of 140 μs. At time 4744 μs, the memory system may transfer data out of the buffer for a duration of 280 μs. At time 5024 μs, the memory system may transfer data into the buffer for a duration of 280 μs. At time 5304 μs, the memory system may perform at least a portion of a second QLC program operation (e.g., a second programming pass, a second portion of a first programming pass) for a duration of 2404 μs. In some examples, the second QLC program operation may be performed during a duration in which the die 405-a is dedicated to performing At time 7708 μs, the memory system may perform a QLC read for a duration of 77 μs.

The memory system may perform various operations 410-b on die 405-b. For example, at start time 0 μs, the memory system may perform a TLC read, for 140 μs. At time 140 μs, the memory system may transfer data out of the buffer, with the transfer duration being 280 μs. At time 420 μs, the memory system may transfer data into buffer for a duration of 280 μs. At time 700 μs, the memory system may perform a QLC program operation for a duration of 2404 μs. At time 3104 μs, the memory system may perform a QLC read for a duration of 77 μs, such as to verify the success of the QLC program operation. The QLC program operation may correspond to at least a portion of a program operation 320. At time 3181 μs, the memory system may transfer data out of the buffer for a duration of 280 μs. At time 3461 μs, the memory system may perform a TLC read for a duration of 140 μs. At 3601 μs, the memory system may transfer data out of the buffer for a duration of 280 μs. At time 3881 μs, the memory system may transfer data into the buffer for a duration of 280 μs. At time 4161 μs, the memory system may perform a second QLC program operation for a duration of 2404 μs. At time 6565 μs, the memory system may perform a second QLC read for a duration 77 μs to verify the success of the second QLC program operation. At 6642 μs, the memory system may transfer data out of the buffer for a duration of 280 μs. At time 6922 μs, the memory system may perform a TLC transfer for a duration of 210 μs. At time 7132 μs, the memory system may perform a TLC program operation on the die 405-b for a duration of 933 μs.

Both dies 405 may perform QLC program operations at the same time (e.g., the first QLC TPROG corresponding to die 405-a overlaps in time with the first QLC TPROG corresponding to die 405-b). One die 405 may perform a write operation (e.g., TLC program operation) while the other die 405 may perform a QLC program operation (e.g., the TLC TPROG corresponding to die 405-a overlaps in time with the first QLC TPROG corresponding to die 405-b, the TLC TPROG corresponding to die 405-b overlaps in time with the second QLC TPROG corresponding to die 405-a). In some examples, the memory system may alternate on which dies 405 the memory performs a TLC program operation. In some examples, the memory system may track respective statuses of the various operations 410 on the dies 405. Such tracking may enable the memory system to switch between performing different operations 410 (e.g., suspending and resuming various operations 410). In some examples, both dies 405 may remain occupied (e.g., no die 405 spends time idle).

FIG. 5 shows a block diagram 500 of a memory system 520 that supports parallel folding and host write handling in accordance with examples as disclosed herein. The memory system 520 may be an example of aspects of a memory system as described with reference to FIGS. 1 through 4. The memory system 520, or various components thereof, may be an example of means for performing various aspects of parallel folding and host write handling as described herein. For example, the memory system 520 may include a folding component 525, a command component 530, a write component 535, a status component 540, or any combination thereof. Each of these components may communicate, directly or indirectly, with one another (e.g., via one or more buses).

The folding component 525 may be configured as or otherwise support a means for performing, at a first die of a memory system (e.g., the memory system 520) during a duration, a first program operation as part of a transfer of first data from a source data block of the first die to a destination data block of the first die, the duration including a length to perform the first program operation. The command component 530 may be configured as or otherwise support a means for receiving, from a host system, a command to write second data to the memory system during the duration. The write component 535 and the folding component 525 may be configured as or otherwise support a means for performing, during the duration and based at least in part on the command, a write operation to write the second data to a second die of the memory system (e.g., by the write component 535) and at least a portion of a second program operation as part of a transfer of third data from a source data block of the second die to a destination data block of the second die (e.g., by the folding component 525).

In some examples, to support performing at least the portion of the second program operation, the folding component 525 may be configured as or otherwise support a means for initiating, before receiving the command, the second program operation to program the second data to the destination data block of the second die. In some examples, to support performing at least the portion of the second program operation, the folding component 525 may be configured as or otherwise support a means for suspending the second program operation based at least in part on initiating the write operation in response to receiving the command. In some examples, to support performing at least the portion of the second program operation, the folding component 525 may be configured as or otherwise support a means for resuming the second program operation after the write operation has been performed.

In some examples, to support performing the write operation, the write component 535 may be configured as or otherwise support a means for performing the write operation while the second program operation is suspended.

In some examples, the status component 540 may be configured as or otherwise support a means for tracking a status of the second program operation, where the second program operation is resumed based at least in part on tracking the status.

In some examples, the second program operation is suspended and the write operation is performed based at least in part on a volatile memory device of the memory system from which the second data is written being full.

In some examples, the folding component 525 may be configured as or otherwise support a means for performing, at the second die during a second duration after the duration, a third program operation as part of a transfer of fourth data from the source data block of the second die to the destination data block of the second die, the second duration including a second length to perform the third program operation. In some examples, the command component 530 may be configured as or otherwise support a means for receiving, from the host system, a second command to write fifth data to the memory system during the second duration. In some examples, the folding component 525 and the write component 535 may be configured as or otherwise support a means for performing, during the second duration and based at least in part on the second command, a second write operation to write the fifth data to the first die (e.g., by the write component 535) and at least a portion of a fourth program operation as part of a transfer of sixth data from the source data block of the first die to the destination data block of the first die (e.g., by the folding component 525).

In some examples, the third program operation as part of the transfer of the fourth data corresponds to a second programming pass of the transfer of the third data. In some examples, the fourth program operation as part of the transfer of the sixth data corresponds to a second programming pass of the transfer of the first data.

In some examples, to support performing at least the portion of the second program operation, the folding component 525 may be configured as or otherwise support a means for initiating, during the duration, the second program operation. In some examples, to support performing at least the portion of the second program operation, the command component 530 may be configured as or otherwise support a means for determining, at one or more intervals during the duration, whether the command has been received. In some examples, to support performing at least the portion of the second program operation, the folding component 525 may be configured as or otherwise support a means for suspending the second program operation based at least in part on determining at an interval of the one or more intervals that the command has been received.

In some examples, the command component 530 may be configured as or otherwise support a means for receiving, from the host system, a second command to write fourth data to the memory system during the duration. In some examples, the write component 535 may be configured as or otherwise support a means for performing a second write operation to write the fourth data to the second die during the duration based at least in part on temporarily suspending the second program operation in response to the second command.

In some examples, to support performing at least the portion of the second program operation, the folding component 525 may be configured as or otherwise support a means for writing the third data from the source data block of the second die to one or more latches of the memory system. In some examples, to support performing the write operation, the write component 535 may be configured as or otherwise support a means for overwriting the one or more latches with the second data based at least in part on receiving the command after the third data is written to the one or more latches.

In some examples, to support performing at least the portion of the second program operation, the folding component 525 may be configured as or otherwise support a means for rewriting, after the write operation is performed, the third data from the source data block of the second die to the one or more latches based at least in part on the overwriting. In some examples, to support performing at least the portion of the second program operation, the folding component 525 may be configured as or otherwise support a means for initiating a program of the third data to the destination data block of the second die from the one or more latches.

In some examples, the command is received before a start time of the duration.

In some examples, the command is received after a start time of the duration and during the duration.

In some examples, the destination data block of the first die and the destination data block of the second die include QLCs. In some examples, the second data is written to SLCs, MLCs, or TLCs of the second die.

In some examples, a second duration to perform the write operation is less than the duration.

FIG. 6 shows a flowchart illustrating a method 600 that supports parallel folding and host write handling in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include performing, at a first die of a memory system during a duration, a first program operation as part of a transfer of first data from a source data block of the first die to a destination data block of the first die, the duration including a length to perform the first program operation. The operations of 605 may be performed in accordance with examples as disclosed herein. In some examples, aspects of the operations of 605 may be performed by a folding component 525 as described with reference to FIG. 5.

At 610, the method may include receiving, from a host system, a command to write second data to the memory system during the duration. The operations of 610 may be performed in accordance with examples as disclosed herein. In some examples, aspects of the operations of 610 may be performed by a command component 530 as described with reference to FIG. 5.

At 615, the method may include performing, during the duration and based at least in part on the command, a write operation to write the second data to a second die of the memory system and at least a portion of a second program operation as part of a transfer of third data from a source data block of the second die to a destination data block of the second die. The operations of 615 may be performed in accordance with examples as disclosed herein. In some examples, aspects of the operations of 615 may be performed by a write component 535 and a folding component 525 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for performing, at a first die of a memory system during a duration, a first program operation as part of a transfer of first data from a source data block of the first die to a destination data block of the first die, the duration including a length to perform the first program operation; receiving, from a host system, a command to write second data to the memory system during the duration; and performing, during the duration and based at least in part on the command, a write operation to write the second data to a second die of the memory system and at least a portion of a second program operation as part of a transfer of third data from a source data block of the second die to a destination data block of the second die.

Aspect 2: The method, apparatus, or non-transitory computer-readable medium of aspect 1, where performing at least the portion of the second program operation includes operations, features, circuitry, logic, means, or instructions, or any combination thereof for initiating, before receiving the command, the second program operation to program the second data to the destination data block of the second die; suspending the second program operation based at least in part on initiating the write operation in response to receiving the command; and resuming the second program operation after the write operation has been performed.

Aspect 3: The method, apparatus, or non-transitory computer-readable medium of aspect 2, where performing the write operation includes operations, features, circuitry, logic, means, or instructions, or any combination thereof for performing the write operation while the second program operation is suspended.

Aspect 4: The method, apparatus, or non-transitory computer-readable medium of any of aspects 2 through 3, further including operations, features, circuitry, logic, means, or instructions, or any combination thereof for tracking a status of the second program operation, where the second program operation is resumed based at least in part on tracking the status.

Aspect 5: The method, apparatus, or non-transitory computer-readable medium of any of aspects 2 through 4, where the second program operation is suspended and the write operation is performed based at least in part on a volatile memory device of the memory system from which the second data is written being full.

Aspect 6: The method, apparatus, or non-transitory computer-readable medium of any of aspects 1 through 5, further including operations, features, circuitry, logic, means, or instructions, or any combination thereof for performing, at the second die during a second duration after the duration, a third program operation as part of a transfer of fourth data from the source data block of the second die to the destination data block of the second die, the second duration including a second length to perform the third program operation; receiving, from the host system, a second command to write fifth data to the memory system during the second duration; and performing, during the second duration and based at least in part on the second command, a second write operation to write the fifth data to the first die and at least a portion of a fourth program operation as part of a transfer of sixth data from the source data block of the first die to the destination data block of the first die.

Aspect 7: The method, apparatus, or non-transitory computer-readable medium of aspect 6, where the third program operation as part of the transfer of the fourth data corresponds to a second programming pass of the transfer of the third data and the fourth program operation as part of the transfer of the sixth data corresponds to a second programming pass of the transfer of the first data.

Aspect 8: The method, apparatus, or non-transitory computer-readable medium of any of aspects 1 through 7, where performing at least the portion of the second program operation includes operations, features, circuitry, logic, means, or instructions, or any combination thereof for initiating, during the duration, the second program operation; determining, at one or more intervals during the duration, whether the command has been received; and suspending the second program operation based at least in part on determining at an interval of the one or more intervals that the command has been received.

Aspect 9: The method, apparatus, or non-transitory computer-readable medium of any of aspects 1 through 8, further including operations, features, circuitry, logic, means, or instructions, or any combination thereof for receiving, from the host system, a second command to write fourth data to the memory system during the duration and performing a second write operation to write the fourth data to the second die during the duration based at least in part on temporarily suspending the second program operation in response to the second command.

Aspect 10: The method, apparatus, or non-transitory computer-readable medium of any of aspects 1 through 9, where performing at least the portion of the second program operation includes operations, features, circuitry, logic, means, or instructions, or any combination thereof for writing the third data from the source data block of the second die to one or more latches of the memory system, where performing the write operation includes and overwriting the one or more latches with the second data based at least in part on receiving the command after the third data is written to the one or more latches.

Aspect 11: The method, apparatus, or non-transitory computer-readable medium of aspect 10, where performing at least the portion of the second program operation includes operations, features, circuitry, logic, means, or instructions, or any combination thereof for rewriting, after the write operation is performed, the third data from the source data block of the second die to the one or more latches based at least in part on the overwriting and initiating a program of the third data to the destination data block of the second die from the one or more latches.

Aspect 12: The method, apparatus, or non-transitory computer-readable medium of any of aspects 1 through 11, where the command is received before a start time of the duration.

Aspect 13: The method, apparatus, or non-transitory computer-readable medium of any of aspects 1 through 11, where the command is received after a start time of the duration and during the duration.

Aspect 14: The method, apparatus, or non-transitory computer-readable medium of any of aspects 1 through 13, where the destination data block of the first die and the destination data block of the second die include QLCs and the second data is written to SLCs, MLCs, or TLCs of the second die.

Aspect 15: The method, apparatus, or non-transitory computer-readable medium of any of aspects 1 through 14, where a second duration to perform the write operation is less than the duration.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a memory device; and
a controller coupled with the memory device, wherein the controller is configured to cause the apparatus to:
perform, at a first die of the apparatus during a duration, a first program operation as part of a transfer of first data from a source data block of the first die to a destination data block of the first die, the duration comprising a length to perform the first program operation;
receive, from a host system, a command to write second data to the apparatus during the duration; and
perform, during the duration and based at least in part on the command, a write operation to write the second data to a second die of the apparatus and at least a portion of a second program operation as part of a transfer of third data from a source data block of the second die to a destination data block of the second die.

2. The apparatus of claim 1, wherein performing at least the portion of the second program operation is configured to cause the apparatus to:
initiate, before receiving the command, the second program operation to program the second data to the destination data block of the second die;
suspend the second program operation based at least in part on initiating the write operation in response to receiving the command; and
resume the second program operation after the write operation has been performed.

3. The apparatus of claim 2, wherein performing the write operation is configured to cause the apparatus to:
perform the write operation while the second program operation is suspended.

4. The apparatus of claim 2, wherein the controller is further configured to cause the apparatus to:
track a status of the second program operation, wherein the second program operation is resumed based at least in part on tracking the status.

5. The apparatus of claim 2, wherein the second program operation is suspended and the write operation is performed based at least in part on a volatile memory device of the apparatus from which the second data is written being full.

6. The apparatus of claim 1, wherein the controller is further configured to cause the apparatus to:
perform, at the second die during a second duration after the duration, a third program operation as part of a transfer of fourth data from the source data block of the second die to the destination data block of the second die, the second duration comprising a second length to perform the third program operation;
receive, from the host system, a second command to write fifth data to the apparatus during the second duration; and
perform, during the second duration and based at least in part on the second command, a second write operation to write the fifth data to the first die and at least a portion of a fourth program operation as part of a transfer of sixth data from the source data block of the first die to the destination data block of the first die.

7. The apparatus of claim 6, wherein the third program operation as part of the transfer of the fourth data corresponds to a second programming pass of the transfer of the third data, and the fourth program operation as part of the transfer of the sixth data corresponds to a second programming pass of the transfer of the first data.

8. The apparatus of claim 1, wherein performing at least the portion of the second program operation is configured to cause the apparatus to:
initiate, during the duration, the second program operation;
determine, at one or more intervals during the duration, whether the command has been received; and
suspend the second program operation based at least in part on determining at an interval of the one or more intervals that the command has been received.

9. The apparatus of claim 1, wherein the controller is further configured to cause the apparatus to:
receive, from the host system, a second command to write fourth data to the second die during the duration; and
perform a second write operation to write the fourth data to the apparatus during the duration based at least in part on temporarily suspending the second program operation in response to the second command.

10. The apparatus of claim 1, wherein performing at least the portion of the second program operation is configured to cause the apparatus to:
write the third data from the source data block of the second die to one or more latches of the apparatus, wherein performing the write operation comprises:
overwrite the one or more latches with the second data based at least in part on receiving the command after the third data is written to the one or more latches.

11. The apparatus of claim 10, wherein performing at least the portion of the second program operation is configured to cause the apparatus to:
rewrite, after the write operation is performed, the third data from the source data block of the second die to the one or more latches based at least in part on the overwriting; and
initiate a program of the third data to the destination data block of the second die from the one or more latches.

12. The apparatus of claim 1, wherein the command is received before a start time of the duration.

13. The apparatus of claim 1, wherein the command is received after a start time of the duration and during the duration.

14. The apparatus of claim 1, wherein:
the destination data block of the first die and the destination data block of the second die comprise quad-level cells, and
the second data is written to single level cells, multi-level cells, or triple level cells of the second die.

15. The apparatus of claim 1, wherein a second duration to perform the write operation is less than the duration.

16. A non-transitory computer-readable medium storing code comprising instructions which, when executed by a processor of an electronic device, cause the electronic device to:
perform, at a first die of a memory system during a duration, a first program operation as part of a transfer of first data from a source data block of the first die to a destination data block of the first die, the duration comprising a length to perform the first program operation;
receive, from a host system, a command to write second data to the memory system during the duration; and
perform, during the duration and based at least in part on the command, a write operation to write the second data to a second die of the memory system and at least a portion of a second program operation as part of a transfer of third data from a source data block of the second die to a destination data block of the second die.

17. The non-transitory computer-readable medium of claim 16, wherein the instructions to perform at least the portion of the second program operation, when executed by the processor of the electronic device, further cause the electronic device to:
initiate, before receiving the command, the second program operation to program the second data to the destination data block of the second die;
suspend the second program operation based at least in part on initiating the write operation in response to receiving the command; and
resume the second program operation after the write operation has been performed.

18. The non-transitory computer-readable medium of claim 17, wherein the instructions to perform the write operation, when executed by the processor of the electronic device, further cause the electronic device to:
perform the write operation while the second program operation is suspended.

19. A method, comprising:
performing, at a first die of a memory system during a duration, a first program operation as part of a transfer of first data from a source data block of the first die to a destination data block of the first die, the duration comprising a length to perform the first program operation;
receiving, from a host system, a command to write second data to the memory system during the duration; and
performing, during the duration and based at least in part on the command, a write operation to write the second data to a second die of the memory system and at least a portion of a second program operation as part of a transfer of third data from a source data block of the second die to a destination data block of the second die.

20. The method of claim 19, wherein performing at least the portion of the second program operation comprises:
initiating, before receiving the command, the second program operation to program the second data to the destination data block of the second die;
suspending the second program operation based at least in part on initiating the write operation in response to receiving the command; and
resuming the second program operation after the write operation has been performed.
